(19) United States
(12) Patent Application Publication
(10) Pub. No.: US 2024/0170400 A1
(43) Pub. Date: May 23, 2024

(54) MEMORY DEVICE AND MANUFACTURING METHOD OF THE MEMORY DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/317,617

(22) Filed: May 15, 2023

(30) Foreign Application Priority Data
Nov. 17, 2022 (KR) 10-2022-0154616

(51) Int. Cl. H01L 23/528; H10B 41/10; H10B 41/27; H10B 43/10; H10B 43/27

(52) U.S. Cl. CPC H01L 23/5283; H10B 41/10; H10B 41/27; H10B 43/10; H10B 43/27

(57) ABSTRACT

There are provided a memory device and a manufacturing method of the memory device. The memory device includes: a stack structure including a plurality of conductive layers and a plurality of insulating layers, which are alternately stacked in a first direction; a plurality of first plugs disposed in the stack structure, the plurality of first plugs extending in the first direction; and a first support structure disposed in the stack structure, the first support structure being adjacent to at least one of the plurality of first plugs. The first support structure includes an insulating structure and a second plug, which are stacked in the first direction. Each of the plurality of first plugs and the second plug includes a channel layer.

### CROSS-REFERENCE TO RELATED APPLICATION

The present application claims priority under 35 U.S.C. § 119(a) to Korean patent application number 10-2022-0154616 filed on Nov. 17, 2022, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a three-dimensional memory device and a manufacturing method of the three-dimensional memory device.

### 2. Related Art

A memory device may be classified as a volatile memory device in which stored data disappears when the supply of power is interrupted or as a nonvolatile memory device in which stored data is retained even when the supply of power is interrupted.

The nonvolatile memory device may include a NAND flash memory, a NOR flash memory, a resistive random access memory (ReRAM), a phase-change random access memory (PRAM), a magnetoresistive random access memory (MRAM), a ferroelectric random access memory (FRAM), a spin transfer torque random access memory (STT-RAM), and the like.

A NAND flash memory system may include a memory device configured to store data and a controller configured to control the memory device. The memory device may include a memory cell array in which data is stored and peripheral circuits configured to perform a program, read or erase operation in response to a command transmitted from the controller.

The memory cell array may include a plurality of memory blocks, and each of the plurality of memory blocks may include a plurality of memory cells.

### SUMMARY

In accordance with an aspect of the present disclosure, there is provided a memory device including: a stack structure including a plurality of conductive layers and a plurality of insulating layers, which are alternately stacked in a first direction; a plurality of first plugs disposed in the stack structure, the plurality of first plugs extending in the first direction; and a first support structure disposed in the stack structure, the first support structure being adjacent to at least one of the plurality of first plugs, wherein the first support structure includes an insulating structure and a second plug, which are stacked in the first direction, and wherein each of the plurality of first plugs and the second plug includes a channel layer. In accordance with another aspect of the present disclosure, there is provided a memory device including: a first stack structure including a plurality of first insulating layers and a plurality of first conductive patterns, which are alternately stacked in a first direction; a second stack structure including a plurality of second insulating layers and a plurality of second conductive patterns, which are alternately stacked in the first direction, wherein the second stack structure is formed on the first stack structure; a first plug extending through the first stack structure and the second stack structure; an insulating structure disposed in the first stack structure; and a second plug disposed in the second stack structure, the second plug being connected to the insulating structure in the first direction, wherein each of the first plug and the second plug includes a channel layer.

In accordance with still another aspect of the present disclosure, there is provided a method of manufacturing a memory device, the method including: forming a first stack structure including a plurality of first and second material layers alternately disposed in a first direction; forming a first gap fill layer and an insulating structure in the first stack structure; forming a second stack structure including third and fourth material layers alternately disposed in the first direction on the first stack structure; forming, in the second stack structure, a first upper hole exposing the first gap fill layer and a second upper hole exposing the insulating structure; forming a first lower hole in the first stack structure by removing the first gap fill layer; forming a first plug in the first lower hole and the first upper hole extending through the first and second stack structures; and forming a second plug in the second upper hole, the second plug extending through the second stack structure and being connected to the insulating structure.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device in accordance with an embodiment of the present disclosure.

FIG. 2 is a diagram illustrating an arrangement structure of a memory cell array and a peripheral circuit.

FIG. 3 is a view illustrating a layout of the memory cell array.

FIG. 4A is a sectional view of a memory device taken along line A-A′ shown in FIG. 3 in accordance with an embodiment of the present disclosure.

FIG. 4B is a sectional view of the memory device taken along line B-B′ shown in FIG. 3 in accordance with the embodiment of the present disclosure.

FIGS. 5A to 5L are sectional views illustrating a manufacturing method of a memory device in accordance with an embodiment of the present disclosure.

FIGS. 6A and 6B are sectional views illustrating a replace process described with reference to FIG. 5L.

FIG. 7 is a diagram illustrating a Solid State Drive (SSD) system to which the memory device of the present disclosure is applied.

FIG. 8 is a diagram illustrating a memory card system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, it will be understood that, although the terms “first,” “second,” etc. may be used herein to describe various elements, these elements should not be limited by these terms. These terms are only used to distinguish one element from another element, and the order or number of components is not limited by the terms.

Embodiments provide a memory device and a manufacturing method of the memory device, which can improve structural stability.

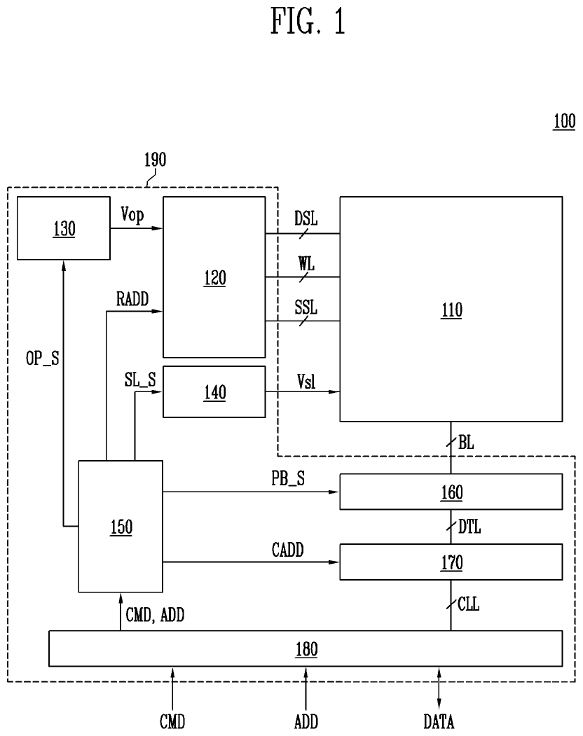

FIG. 1 is a diagram illustrating a memory device in accordance with an embodiment of the present disclosure.

Referring to FIG. 1, the memory device 100 may include a peripheral circuit 190 and a memory cell array 110.

The peripheral circuit 190 may be configured to perform a program operation and a verify operation, which are used to store data, to perform a read operation for outputting data stored in the memory cell array 110, or to perform an erase operation for erasing data stored in the memory cell array 110. The peripheral circuit 190 may include a voltage generating circuit 130, a row decoder 120, a source line driver 140, a control circuit 150, a page buffer 160, a column decoder 170, and an input/output circuit 180.

The memory cell array 110 may include a plurality of memory cells in which data is stored. In an embodiment, the memory cell array 110 may include a three-dimensional memory cell array. The plurality of memory cells may store single-bit data or multi-bit data of two or more bits according to a program manner. The plurality of memory cells may constitute a plurality of strings. Memory cells included in each of the strings may be electrically connected to each other through a channel. Channels included in the strings may be connected to the page buffer 160 through bit lines BL.

The voltage generating circuit 130 may generate various operating voltages Vop used for a program operation, a read operation, or an erase operation in response to an operation signal OP_S. For example, the voltage generating circuit 130 may selectively generate and output the operating voltages Vop including a program voltage, a verify voltage, a pass voltage, a read voltage, an erase voltage, and the like.

The row decoder 120 may be connected to the memory cell array 110 through a plurality of drain select lines DSL, a plurality of word lines WL, and a plurality of source select lines SSL. The row decoder 120 may transfer the operating voltages Vop to the plurality of drain select lines DSL, the plurality of word lines WL, and the plurality of source select lines SSL in response to a row address RADD.

The source line driver 140 may transmit a source voltage Vsl to the memory cell array 110 in response to a source line control signal SL_S. For example, the source voltage Vsl may be transferred to a source line connected to the memory cell array 110.

The control circuit 150 may output the operation signal OP_S, the row address RADD, the source line control signal SL_S, a page buffer control signal PB_S, and a column address CADD, in response to a command CMD and an address ADD.

The page buffer 160 may be connected to the memory cell array 110 through the bit lines BL. The page buffer 160 may temporarily store data DATA received through a plurality of bit lines BL in response to the page buffer control signal PB_S. The page buffer 160 may sense a voltage or current of the plurality of bit lines BL in a read operation.

In response to the column address CADD, the column decoder 170 may transmit data DATA input from the input/output circuit 180 to the page buffer 160 or transmit data DATA stored in the page buffer 160 to the input/output circuit 180. The column decoder 170 may exchange data DATA with the input/output circuit 180 through column lines CLL and may exchange data DATA with the page buffer 160 through data lines DTL.

The input/output circuit 180 may transfer, to the control circuit 150, a command CMD and an address ADD, which are transferred from an external device (e.g., a controller) connected to the memory device 100, and may output data received from the column decoder 170 to the external device.

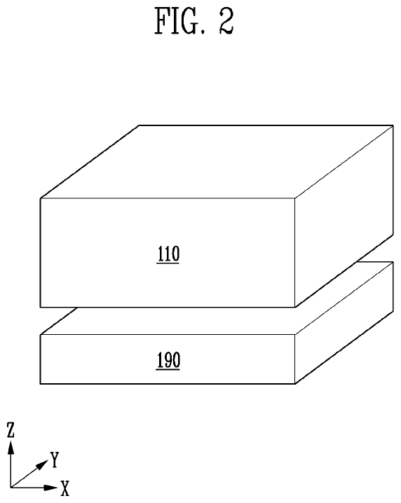

FIG. 2 is a diagram illustrating an arrangement structure of the memory cell array and the peripheral circuit.

Referring to FIG. 2, the memory cell array 110 may be stacked above the peripheral circuit 190. For example, the peripheral circuit 190 and the memory cell array 110 may be formed on a substrate extending along an X-Y plane. The peripheral circuit 190 and the memory cell array 110 may be stacked in a Z direction.

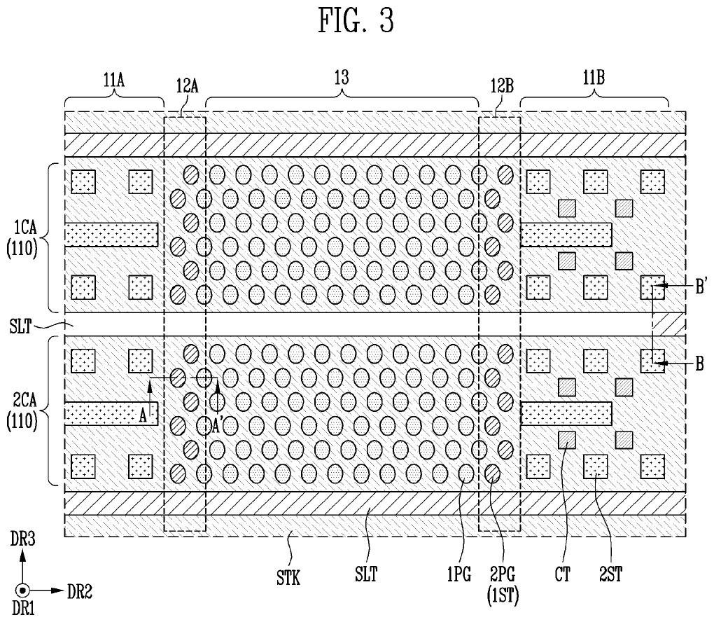

FIG. 3 is a view illustrating a layout of the memory cell array.

Referring to FIG. 3, the memory cell array 110 may include a plurality of sub-cell arrays. Hereinafter, the embodiment of the present disclosure will be described based on first and second sub-cell arrays 1CA and 2CA, among the plurality of sub-cell arrays.

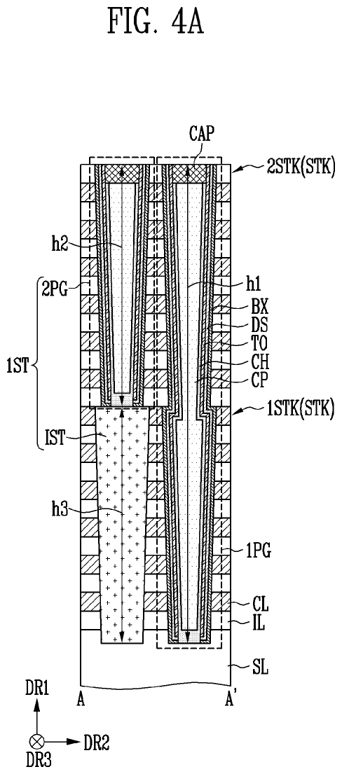

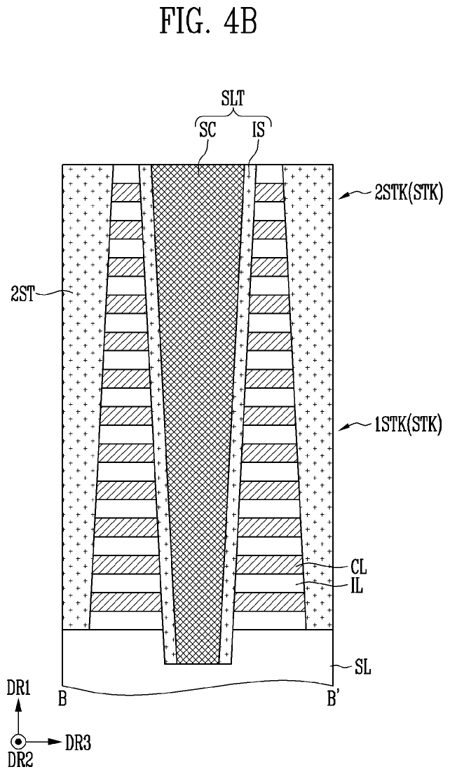

Each of the first and second sub-cell arrays 1CA and 2CA may include a plurality of first plugs 1PG. The plurality of first plugs 1PG may be disposed in a stack structure STK, shown in FIGS. 4A and 4B. The plurality of first plugs 1PG may extend in a direction in which a plurality of layers of the stack structure STK are stacked. A plurality of first support structures 1ST and a plurality of second support structures 2ST may be further disposed in the stack structure STK, shown in FIGS. 4A and 4B. The plurality of first support structures 1ST and the plurality of second support structures 2ST may extend in a first direction DR1.

A stack structure of the first sub-cell array 1CA and a stack structure of the second sub-cell array 2CA may extend in an extending direction of a slit SLT. In an embodiment, the slit SLT may extend in a second direction DR2. The stack structure of the first sub-cell array 1CA and the stack structure of the second sub-cell array 2CA may extend along the second direction DR2. The stack structure of the first sub-cell array 1CA and the stack structure of the second sub-cell array 2CA may be arranged to be spaced apart from each other in a third direction DR3. More specifically, the stack structure of the first sub-cell array 1CA and the stack structure of the second sub-cell array 2CA may be isolated from each other by the slit SLT. In other words, the slit SLT may be arranged between the first and second sub-cell arrays 1CA and 2CA.

Each of the first and second sub-cell arrays 1CA and 2CA may include first regions 11A and 11B, second regions 12A and 12B, and a third region 13. The first regions 11A and 11B may include a 1Ath region 11A and a 1Bth region 11B, which are spaced apart from each other with the third area 13 interposed therebetween. The second regions 12A and 12B may include a 2Ath region 12A arranged between the 1Ath region 11A and the third region 13 and a 2Bth region 12B arranged between the 1Bth region 11B and the third region 13. In an embodiment, the 1Ath region 11A may be a region adjacent to an end portion of the stack structure STK, shown in FIGS. 4A and 4B, and the 1Bth region 11B may be a region in which a stepped structure of the stack structure STK, shown in FIGS. 4A and 4B, is disposed.

The 1Ath and 1Bth regions 11A and 11B may include a plurality of support structures 2ST. The 1Bth region 11B may include a stepped structure connected to a plurality of contact plugs CT. That is, the 1Bth region 11B may be defined as a contact region connected to the plurality of contact plugs CT. Although the contact plugs CT and the second support structures ST2 are illustrated in a quadrangular shape in the drawing, the shape of the contact plug CT and the second support structure 2ST is not limited to the shape shown in the drawing. For example, the contact plugs CT and the second support structures 2ST may be formed in a polygonal shape, such as a triangular shape, a circular shape, or an elliptical shape.

The third region 13 may include a plurality of first plugs 1PG. A string including a plurality of memory cells connected in series may be defined along each first plug 1PG. The third region 13 may surround the plurality of first plugs 1PG and may be defined as a cell region. An upper end of the plurality of first support structures 1ST disposed in the 2Ath and 2Bth regions 12A and 12B may include a plurality of second plugs 2PG. Each second plug 2PG may be formed of the same materials as the first plug 1PG. Although each of the first and second plugs 1PG and 2PG is illustrated in a circular shape in the drawing, the shape of each of the first and second plugs 1PG and 2PG is not limited to the shape shown in the drawing. For example, the first and second plugs 1PG and 2PG may be formed in a polygonal shape, such as a quadrangular shape, or an elliptical shape. The structure of the first and second plugs 1PG and 2PG will be described in more detail later with reference to FIG. 4A.

A lower end of the plurality of first support structures 1ST may include a plurality of insulating structures IST as shown in FIG. 4A. The plurality of second plugs 2PG may overlap with the plurality of insulating structures IST as shown in FIG. 4A. The plurality of insulating structures IST, shown in FIG. 4A, may be respectively connected to the bottom of the plurality of second plugs 2PG. A second plug 2PG and the insulating structure (IST shown in FIG. 4A), which are connected to each other, may be defined as a first support structure 1ST. The structure of the first and second support structures 1ST will be described in more detail later with reference to FIGS. 4A and 4B.

The 2Ath and 2Bth regions 12A and 12B including the plurality of first support structure 1ST may be disposed to be adjacent to each other in the third region 13 including the plurality of first plugs 1PG. The third region 13 may be adjacent to the 2Ath region 12A in the second direction DR2, which is the direction in which the slit SLT extends, and the 2Bth region 12B may be adjacent to the third region 13 in the second direction DR2. Accordingly, at least one first plug, among the plurality of first plugs 1PG, may be disposed to be adjacent to the first support structure 1ST in the second direction DR2. The 1Ath region 11A and the 1Bth region 11B, which include the plurality of second support structures 2ST, may be respectively disposed to be adjacent to the 2Ath region 12A and the 2Bth region 12B, which include the plurality of first support structures 1ST. The 1Ath region 11A and the 1Bth region 11B may be disposed at both ends of each of the first and second sub-cell arrays 1CA and 2CA with the 2Ath region 12A, the 2Bth region 12B, and the third region 13, which are interposed therebetween. Therefore, the second support structures 2ST may be disposed at both ends of each of the first and second sub-cell arrays 1CA and 2CA with the first support structures 1ST and the first plugs 1PG, which are interposed therebetween. The 2Ath region 12A may be disposed between the 1Ath region 11A and the third region 13, and the 2Bth region 12B may be disposed between the 1Bth region 11B and the third region 13. Therefore, the plurality of first support structures 1ST may be disposed between the plurality of second support structures 2ST and the plurality of first plugs 1PG.

Each first plug 1PG may be connected to a bit line (not shown) corresponding thereto. The bit line may extend in a direction that intersects the slit SLT and may be connected to a first plug 1PG of the first sub-cell array 1CA and a first plug 1PG of the second sub-cell array 2CA. For example, the bit line may extend along the third direction DR3. The second plug 2PG may be a dummy plug. Any signal line might not be connected to the second plug 2PG, or a bit line corresponding to the second plug 2PG may be additionally disposed and may be connected to the second plug 2PG.

FIG. 4A is a sectional view of a memory device taken along line A-A′ shown in FIG. 3 in accordance with an embodiment of the present disclosure. FIG. 4B is a sectional view of the memory device taken along line B-B′ shown in FIG. 3 in accordance with the embodiment of the present disclosure.

Referring to FIGS. 4A and 4B, each of the first sub-cell array 1CA and the second sub-cell array 2CA, which are described with reference to FIG. 3, may include a stack structure STK. The stack structure STK may include a plurality of conductive layers CL and a plurality of insulating layers IL, which are alternately stacked in the first direction DR1 on a source layer SL. The stack structure STK may include a first stack structure 1STK and a second stack structure 2STK on the first stack structure 1STK. The plurality of conductive layers CL and the plurality of insulating layers IL may include conductive and insulating layers of the first stack structure 1STK and conductive and insulating layers of the second stack structure 2STK. The plurality of conductive layers CL may be used as the drain select line DSL, the plurality of word lines WL, and the source select line SSL, which are shown in FIG. 1.

Referring to FIG. 4A, a first plug 1PG and a first support structure 1ST, which extend in the first direction DR1, may be disposed in the stack structure STK. The first support structure 1ST may include an insulating structure IST and a second plug 2PG, which are stacked in the first direction DR1. The insulating structure IST may overlap with the second plug 2PG and may be connected to the bottom of the second plug 2PG. The second plug 2PG may be disposed in the second stack structure 2STK, and the insulating structure IST may be disposed in the first stack structure 1STK. The first plug 1PG may extend through the first stack structure 1STK and the second stack structure 2STK. A sidewall of the first plug 1PG may have a stepped corner portion at a boundary between the first stack structure 1STK and the second stack structure 2STK.

A length of the first plug 1PG in the first direction DR1 may be defined as a first length h1. A length of the second plug 2PG in the first direction DR1 may be defined as a second length h2. A length of the insulating structure IST in the first direction DR1 may be defined as a third length h3. The second length h2 of the second plug 2PG and the third length h3 of the insulating structure IST may be smaller than the first length h1 of the first plug 1PG. A top surface of the first plug 1PG and a top surface of the second stack structure 2STK may substantially be on the same plane. A top surface of the second plug 2PG and the top surface of the second stack structure 2STK may substantially be on the same plane. A top surface of the insulating structure IST and a plane on which the first stack structure 1STK and the second stack structure 2STK interface may substantially be on the same plane. The bottom of the first plug 1PG may be connected to the source line SL. The first plug 1PG may be directly connected to the source layer SL without any intermediate element. The bottom of the second plug 2PG and the plane on which the first stack structure 1STK and the second stack structure 2STK interface may substantially be on the same plane. The bottom of the second plug 2PG and the stepped corner portion on the sidewall of the first plug 1PG may substantially be on the same plane. The insulating structure IST may be disposed between the second plug 2PG and the source layer SL. The top surface of the insulating structure IST the stepped corner portion on the sidewall of the first plug 1PG may substantially be on the same plane. The bottom of the insulating structure IST may be connected to the source layer SL. The insulating structure IST may be directly connected to the source layer SL without any intermediate element.

Each of the first plug 1PG and the second plug 2PG may include a blocking layer BX, a data storage layer DS, a tunnel insulating layer TO, a channel layer CH, a core pillar CP, and a capping layer CAP. The capping layer CAP may be disposed at a top end of the first plug 1PG and the second plug 2PG. The capping layer CAP may be formed of a conductive material. For example, the capping layer CAP may be formed of a doped poly-silicon layer. The core pillar CP may be disposed on the bottom of the capping layer CAP. For example, the core pillar CP may be formed of an insulating material or a conductive material. The channel layer CH may extend along a sidewall of each of the capping layer CAP and the core pillar CP. The channel layer CH may be formed of a semiconductor material. For example, the channel layer CH may be formed of a poly-silicon layer. The tunnel insulating layer TO may extend along a sidewall of the channel layer CH. The tunnel insulating layer TO may be formed to surround the channel layer CH and may be formed of an insulating material. For example, the tunnel insulating layer TO may be formed of an oxide layer, such as a silicon oxide layer. The data storage layer DS may extend along a sidewall of the tunnel insulating layer TO. The data storage layer DS may be formed to surround the tunnel insulating layer TO. The data storage layer DS may include a material capable of storing data in various manners, such as a charge trap layer, a variable resistance layer, or a nano dot. For example, the data storage layer DS may be formed of a nitride layer capable of trapping charges. The blocking layer BX may extend along a sidewall of the data storage layer DS. The blocking layer BX may be formed to surround the data storage layer DS and may be formed of an insulating material. For example, the blocking layer BX may be formed of an oxide layer, such as a silicon oxide layer.

The channel layer CH of the first plug 1PG may be directly connected to the source layer SL. Specifically, the bottom of the channel layer CH of the first plug 1PG may be connected to the source layer SL. However, the embodiment of the present disclosure is not limited thereto, and the source layer SL may be changed in a form in which the source layer SL penetrates a portion of each of the blocking layer BX, the data storage layer DS, and the tunnel insulating layer TO, which are formed on the sidewall of the first plug 1PG. The channel layer CH of the first plug 1PG may include a sidewall directly connected to the source layer SL.

The channel layer CH of the second plug 2PG may be directly connected to the insulating structure 1ST. Specifically, the bottom of the channel layer CH of the second plug 2PG may be connected to the insulating structure IST. The channel layer CH of the second plug 2PG may be disposed to be spaced apart from the source layer SL by the insulating structure IST.

Referring to FIG. 4B, a slit SLT and a plurality of second support structures 2ST, which extend in the first direction DR1, may be disposed in the stack structure STK. The slit SLT may be filled with at least one of a conductive material and an insulating material. In an embodiment, the slit SLT may be filled with a source contact SC and a slit insulating layer IS. The slit insulating layer IS may be disposed to cover a sidewall of the source contact SC. The source contact SC may be connected to the source layer SL and may be formed of a conductive material. The plurality of second support structures 2ST may be disposed at both sides of the slit SLT. Each second support structure 2ST may be formed of an insulating material. For example, each second support structure 2ST may be formed of oxide, such as silicon oxide.

The slit SLT and the second support structure 2ST may extend through the first stack structure 1STK and the second stack structure 2STK. The slit SLT and the second support structure 2ST may overlap with the source layer SL. The bottom of the source contact SC may be connected to the source layer SL.

Referring to FIGS. 4A and 4B, the second support structure 2ST, shown in FIG. 4B, may extend longer in the first direction DR1 than the insulating structure IST of the first support structure 1ST, shown in FIG. 4A. While the top surface of the insulating structure IST of the first support structure 1ST overlaps with the boundary between the first stack structure 1STK and the second stack structure 2STK on the first stack structure 1STK, a top surface of the insulating material constituting the second support structure 2ST may overlap with the top surface of the second stack structure 2STK.

While the sidewall of the first plug 1PG, shown in FIG. 4A, includes the stepped corner portion disposed at the boundary between the first stack structure 1STK and the second stack structure 2STK, a sidewall of each of the second support structure 2ST and the slit SLT, which are shown in FIG. 4B, might not include the stepped corner portion disposed at the boundary between the first stack structure 1STK and the second stack structure 2STK.

Although the embodiment of the present disclosure is illustrated based on the structure in which the stack structure STK includes the first and second stack structures 1STK and 2STK, the number of stack structures included in the stack structure STK is not limited to the number shown in the drawings. For example, the stack structure STK may include first to third stack structures. The number of second plugs 2PG on the insulating structure IST is not limited to the number shown in the drawings. For example, a total of two second plugs 2PG including a lower second plug connected to the insulating structure IST and an upper second plug connected to the lower second plug may be formed on the insulating structure IST.

The first support structure 1ST and the second support structure 2ST, which are shown in FIGS. 4A and 4B, can improve the structural stability of the stack structure STK in a process of manufacturing the memory device. As compared with a structure in which the insulating structure IST is omitted on the bottom of the second plug 2PG of the first support structure 1ST as shown in FIG. 4A, a structure in which the insulating structure IST is formed on the bottom of the second plug 2PG can further improve the structural stability.

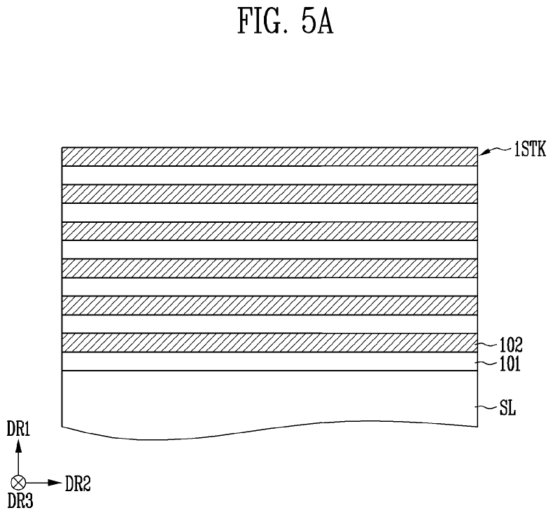

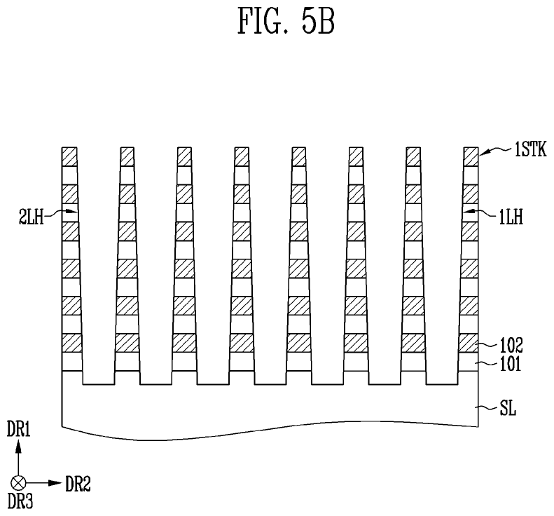

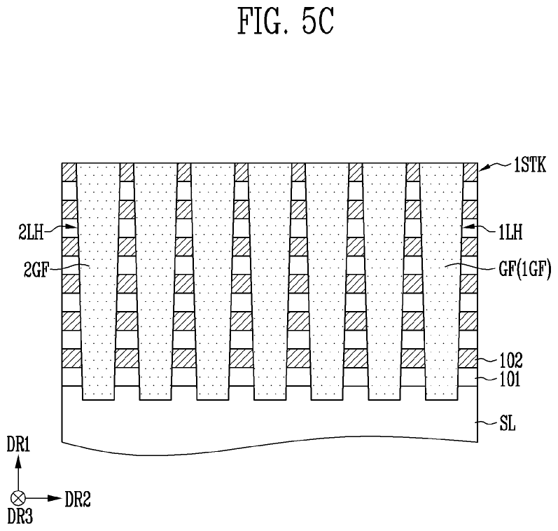

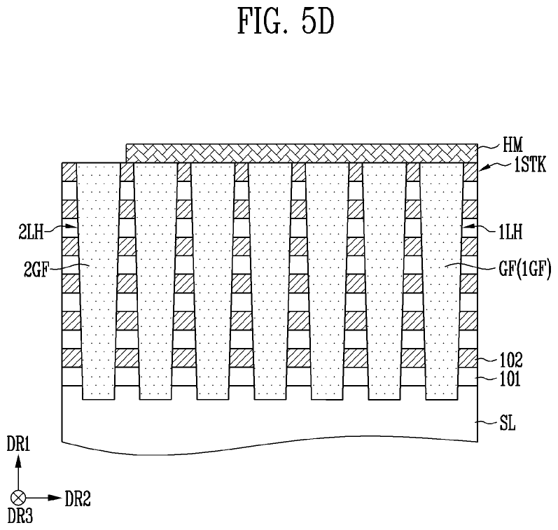

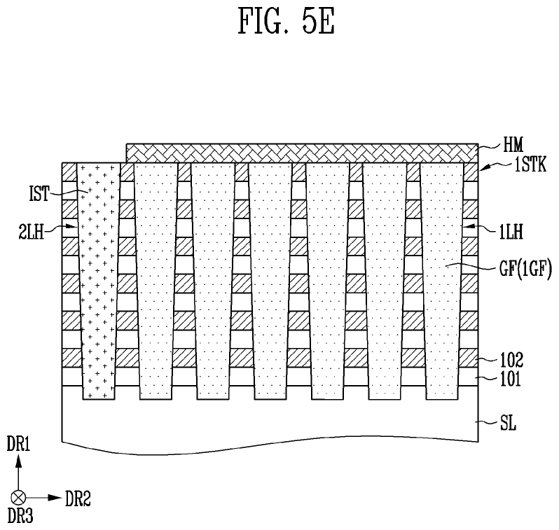

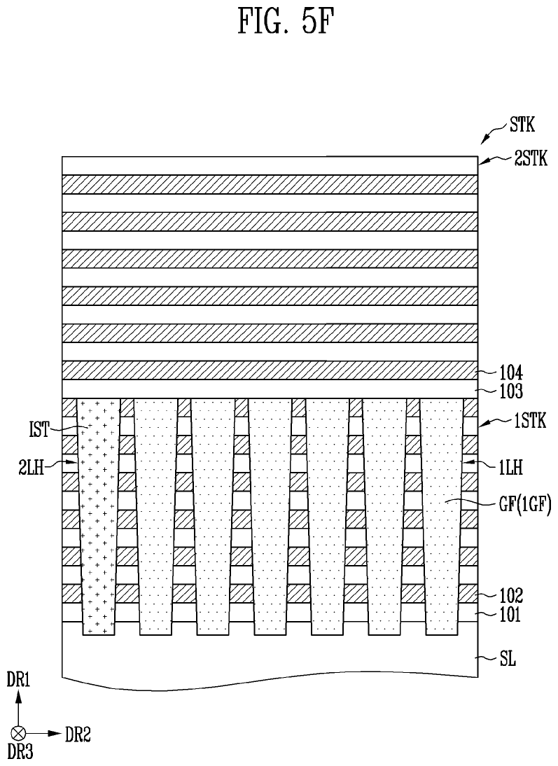

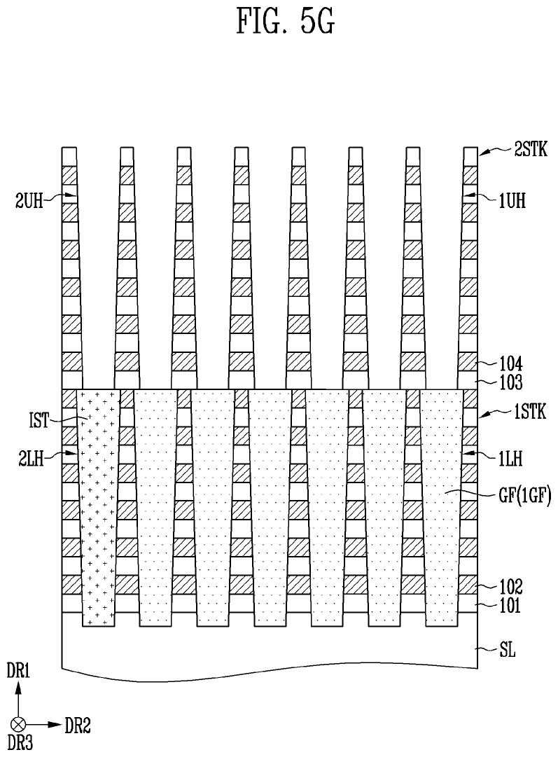

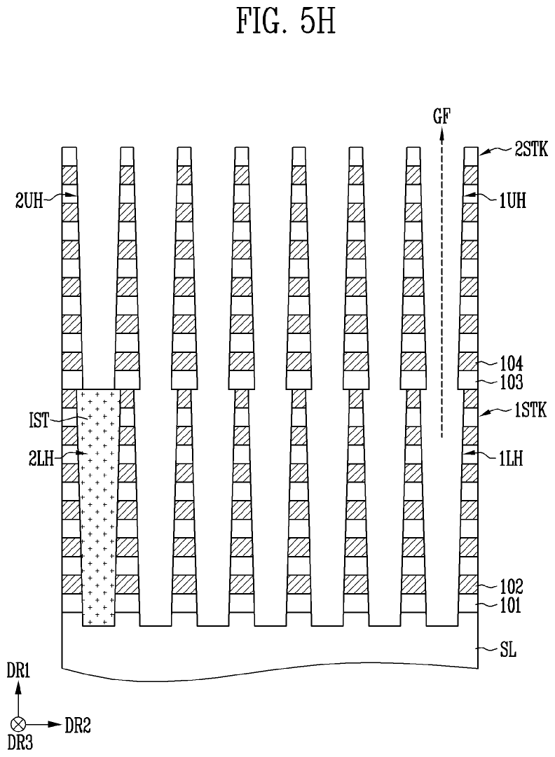

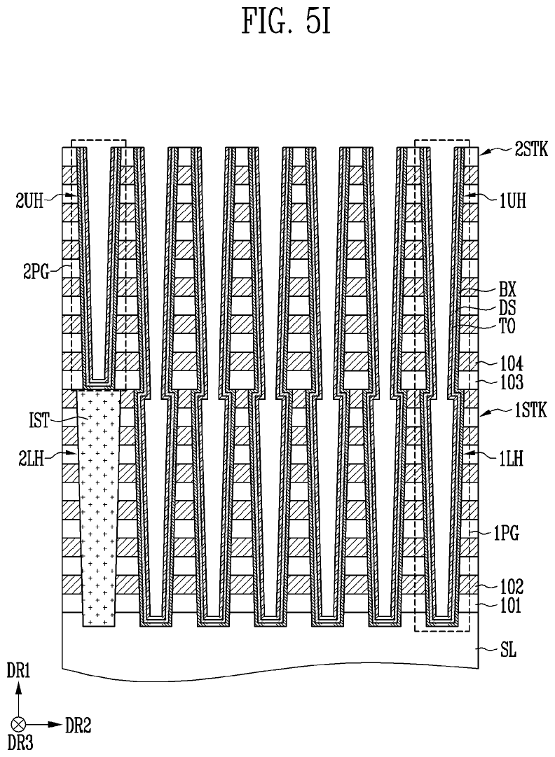

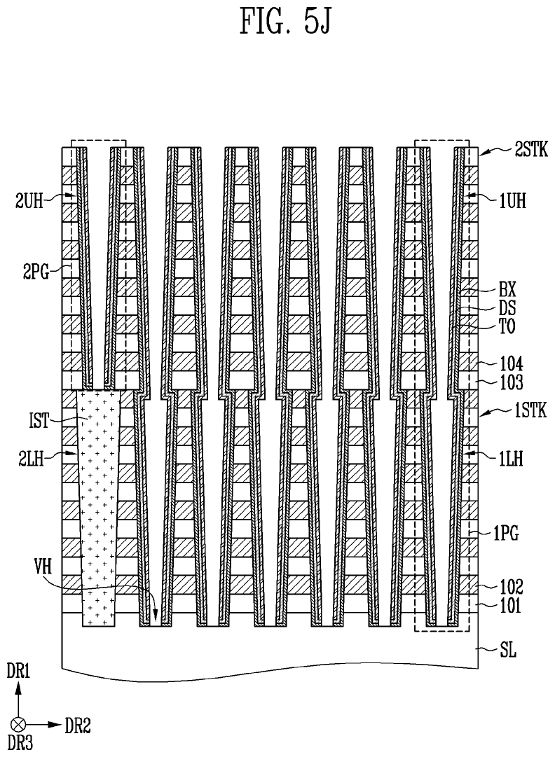

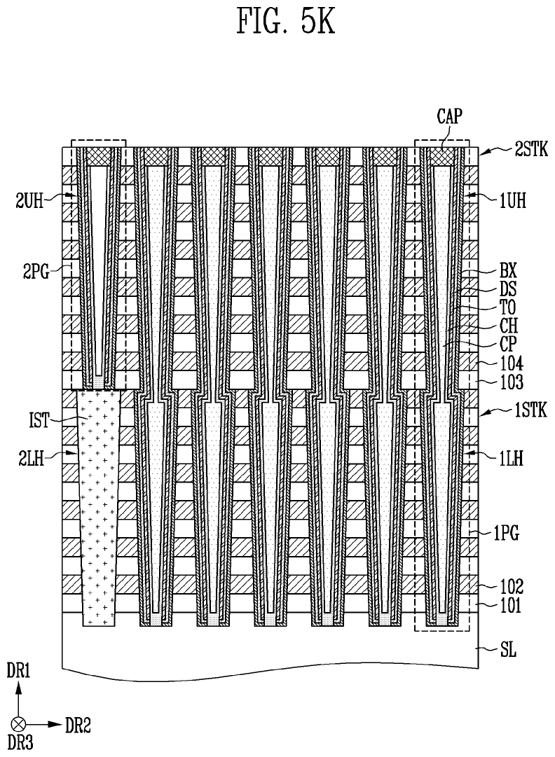

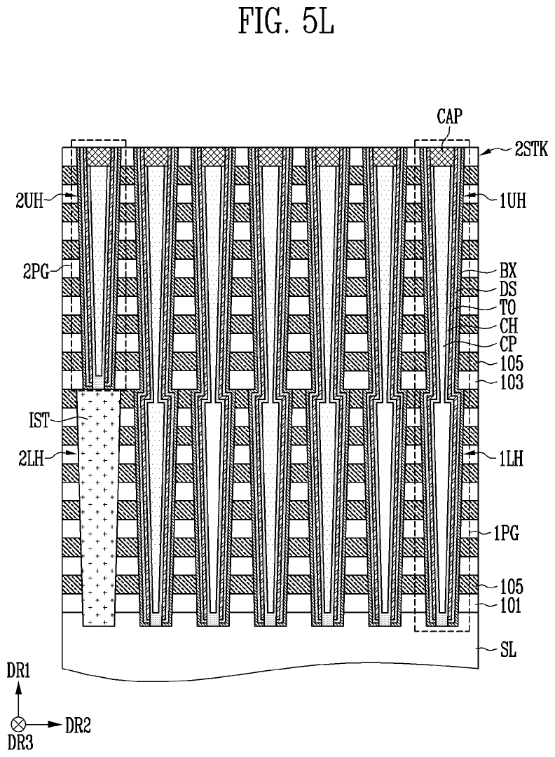

FIGS. 5A to 5L are sectional views illustrating a manufacturing method of a memory device in accordance with an embodiment of the present disclosure.

Referring to FIG. 5A, a source layer SL may be stacked on a lower structure (not shown). The lower structure (not shown) may be a structure including a substrate or peripheral circuits. Since the source layer SL is a layer used as a source line, the source layer SL may be formed of a conductive material. For example, the source layer SL may be formed of a conductive material, such as poly-silicon, tungsten, or nickel. For example, the source layer SL may be formed in a structure in which first to third poly-silicon layers and an insulating layer are alternately stacked. A poly-silicon layer may be located at a lowermost portion and an uppermost portion of the source layer SL. A first material layer 101 and a second material layer 102 may be alternately stacked on the top of the source layer SL. For example, when a first material layer 101 is formed on the source layer SL, a second material layer 102 may be formed on the first material layer 101 formed on the source layer SL, and a first material layer 101 may be again formed on the second material layer 102 formed on the first material layer 101. The first material layer 101 may be formed of an insulating material. For example, the first material layer 101 may be formed of an oxide layer, such as a silicon oxide layer. The second material layer may be formed of a material that can be removed in a subsequent process. Therefore, the second material layer 102 may be formed of a material having an etch selectivity that is different from an etch selectivity of the first material layer 101. For example, the second material layer 102 may be formed of a nitride layer. Accordingly, a first stack structure 1STK may be formed.

Referring to FIG. 5B, first and second lower holes 1LH and 2LH penetrating the first and second material layers 101 and 102 may be formed in the first stack structure 1STK. An etching process for removing portions of the first and second material layers 101 and 102 may be performed so as to form the first and second lower holes 1LH and 2LH. In an embodiment, the first and second material layers 101 and 102 may be etched through a dry etching process such that the first and second lower holes 1LH and 2LH extend in the first direction DR1 vertical to a surface of each of the first and second material layers 101 and 102. The first and second material layers 101 and 102 may be exposed through inner walls of the first and second lower holes 1LH and 2LH. The first lower hole 1LH may be used to form a first plug. The second lower hole 2LH may be used to form an insulating structure.

Referring to FIG. 5C, gap fill layers GF may be formed in the first and second lower holes 1LH and 2LH. The gap fill layers GF may include a first gap fill layer 1GF disposed in the first lower hole 1LH and a second gap fill layer 2GF disposed in the second lower hole 2LH. Each gap fill layer GF may include at least one of tungsten (W), carbon (C), and molybdenum (Mo).

Referring to FIG. 5D, a hard mask HM may be formed on the first stack structure 1STK. The first gap fill layer 1GF may be blocked by the hard mask HM, and the second gap fill layer 2GF may be exposed by the hard mask HM. That is, the hard mask HM may be formed to cover an upper surface of the first gap fill layer 1GF, but an upper surface of the second gap fill layer 2GF may be formed to be exposed.

Referring to FIG. 5E, the second gap fill layer 2GF, shown in FIG. 5D, may be removed such that the second lower hole 2LH is opened. Since the upper surface of the second gap fill layer 2GF, shown in FIG. 5D, is exposed by the hard mask HM, only the second gap fill layer 2GF, among the gap fill layers GF, may be selectively removed. The bottom of the second lower hole 2LH may be exposed through an etching process that removes the second gap fill layer 2GF. Subsequently, an insulating structure IST may be formed in the second lower hole 2LH. The insulating structure IST may be formed of an insulating material, e.g., oxide, such as silicon oxide.

Referring to FIG. 5F, the hard mask HM, shown in FIG. 5E, may be removed. Accordingly, the first stack structure 1STK and the first gap fill layer 1GF may be exposed. After that, third and fourth material layers 103 and 104 may be alternately stacked on the first stack structure 1STK. For example, when a third material layer 103 is formed on the first stack structure 1STK, a fourth material layer 104 may be formed on the third material layer 103, and a third material layer 103 may be again formed on the fourth material layer 104. The third material layer 103 may be formed of an insulating material. For example, the third material layer 103 may be formed of an oxide layer, such as a silicon oxide layer. The fourth material layer 104 may be formed of a material that can be selectively removed in a subsequent process. Therefore, the fourth material layer 103 may be formed of a material having an etch selectivity different from an etch selectivity of the third material layer 103. For example, the fourth material layer 104 may be formed of a nitride layer. The third material layer 103 may be formed at a lowermost end and an uppermost end of a stack structure STK including the first stack structure 1STK and a second stack structure 2STK.

Referring to FIG. 5G, first and second upper holes 1UH and 2UH penetrating the third and fourth material layers 103 and 104 may be formed in the second stack structure 2STK. An etching process for removing portions of the third and fourth material layers 103 and 104 may be performed so as to form the first and second upper holes 1UH and 2UH. In an embodiment, the third and fourth material layers 103 and 104 may be etched through a dry etching process such that the first and second upper holes 1UH and 2UH extend in the first direction DR1, vertical to a surface of each of the third and fourth material layers 103 and 104. The third and fourth material layers 103 and 103 may be exposed through inner walls of the first and second upper holes 1UH and 2UH. The first upper hole 1UH may be used to form the first plug. The second upper hole 2UH may be used to form a second plug. The upper surface of the first gap fill layer 1GF may be exposed by the first upper holes 1UH, and an upper surface of the insulating structure IST may be exposed by the second upper hole 2UH.

Referring to FIG. 5H, the first gap fill layer 1GF exposed by the first upper hole 1UH may be removed such that the first lower hole 1LH is opened. Since the first gap fill layer 1GF has an etch selectivity different from an etch selectivity of the insulating structure IST, the first gap fill layer 1GF may be selectively etched, and the insulating structure IST may remain in the second lower hole 2LH.

Referring to FIG. 5I, a blocking layer BX, a data storage layer DS, and a tunnel insulating layer TO may be sequentially formed along surfaces of the first lower hole 1LH and the first upper hole 1UH, thereby forming a preliminary first plug structure. A blocking layer BX, a data storage layer DS, and a tunnel insulating layer TO may be sequentially formed along a surface of the second upper hole 2UH, thereby forming a preliminary second plug structure.

Referring to FIG. 5J, a vertical hole VH penetrating the blocking layer BX, the data storage layer DS, and the tunnel insulating layer TO may be formed in each of the first lower hole 1LH and the second upper hole 2UH, the vertical hole VH extending to a bottom surface of each of the first lower hole 1LH and the second upper hole 2UH. The source layer SL may be exposed at the bottom surface of the first lower hole 1LH through the vertical hole VH, and the insulating structure IST may be exposed at a bottom surface of the second upper hole 2UH.

Referring to FIG. 5K, a channel layer CH may be formed in each of the first lower hole 1LH, the first upper hole 1UH, and the second upper hole 2UH. The channel layer CH may be disposed on the tunnel insulating layer TO and may fill the inside of the vertical hole VH as shown in FIG. 5J. Subsequently, a core pillar CP and a capping layer CAP may be formed along the inside of each of the first lower hole 1LH, the first upper hole 1UH, and the second upper hole 2UH, which are opened by the channel layer CH. The capping layer CAP may be disposed on the core pillar CP. The blocking layer BX, the data storage layer DS, the tunnel insulating layer TO, the channel layer CH, the core pillar CP, and the capping layer CAP, which are disposed in the first lower hole 1LH and the first upper hole 1UH, may be defined as a first plug 1PG. The blocking layer BX, the data storage layer DS, the tunnel insulating layer TO, the channel layer CH, the core pillar CP, and the capping layer CAP, which are disposed in the second upper hole 2UH, may be defined as a second plug 2PG. The channel layer CH of the first plug 1PG may extend along an inner wall of the tunnel insulating layer TO and may be connected to the source layer SL through the vertical hole VH as shown in FIG. 5J. The channel layer CH of the second plug 2PG may extend along an inner wall of the tunnel insulating layer TO and may be connected to the insulating structure IST through the vertical hole VH as shown in FIG. 5J.

Referring to 5L, a replace process may be performed by replacing the second material layer 102 and the second material layer 104, shown in FIG. 5K, with a fifth material layer 105. The fifth material layer 105 may be provided for gate lines, such as a drain select line, a source select line, and word lines, and be formed of a conductive material. For example, the fifth material layer 105 may be formed of tungsten (W), cobalt (Co), nickel (Ni), molybdenum (Mo), silicon (Si), poly-silicon, and the like.

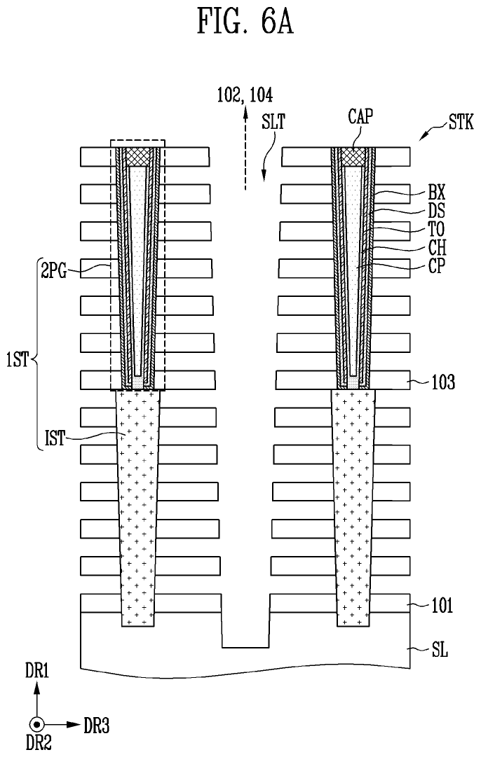

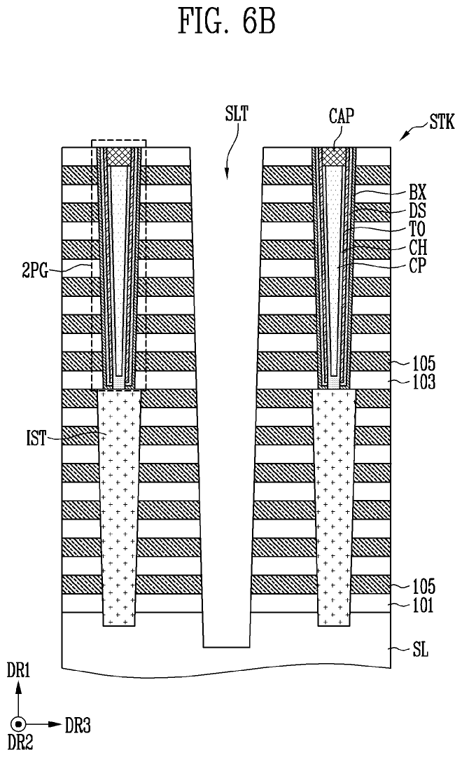

FIGS. 6A and 6B are sectional views illustrating the replace process described with reference to FIG. 5L.

Referring to FIGS. 6A, a slit SLT may be formed, which extends through the first stack structure 1STK and the second stack structure 2SK, shown in FIG. 5K. A layout of the slit SLT may be the same as the layout as shown in FIG. 3. Subsequently, the second material layer 102 and the fourth material layer 104, which are shown in FIG. 5K, may be removed through the slit SLT by using an etching process. The etching process may be performed using an etchant that can allow the first material layer 101 and the third material layer 103 to remain and may selectively remove the second material layer 102 and the fourth material layer 104, which are shown in FIG. 5K.

When the second and fourth material layers 102 and 104, shown in FIG. 5K, are selectively removed, a space between the first and third material layers 101 and 103 may be opened, and therefore, the stack structure STK may structurally become unstable. A gap of the space opened as the fourth material layer is removed can be stably maintained by the second plug 2PG, and a gap of the space opened as the second material layer is removed can be stably maintained by the insulating structure IST. That is, the structure of the first stack structure (1STK shown in FIG. 5L) can be stably supported by the insulating structure IST, and the structure of the second stack structure (2STK shown in FIG. 5L) can be stably supported by the second plug 2PG. Thus, the structural stability of the stack structure STK can be improved. In particular, the supporting force may further be improved by the insulating structure IST formed at a lower portion of the first support structure 1ST so that a phenomenon in which the stack structure STK is bent can be minimized.

Referring to FIG. 6B, the fifth material layer 105, described with reference to FIG. 5L, may be formed in each of the spaces opened as the second material layer and the fourth material layer are removed.

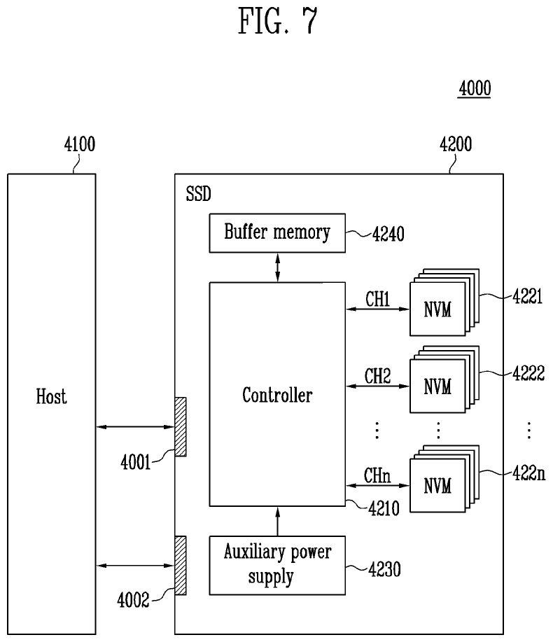

FIG. 7 is a diagram illustrating a Solid State Drive (SSD) system to which the memory device of the present disclosure is applied.

Referring to FIG. 7, the SSD system 4000 may include a host 4100 and an SSD 4200. The SSD 4200 may exchange a signal with the host 4100 through a signal connector 4001 and may be supplied with power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be transmitted based on an interface between the host 4100 and the SSD 4200. For example, the signal may be defined by at least one of interfaces, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100 and may charge the power PWR. When the supply of power from the host 4100 is not smooth, the auxiliary power supply 4230 may provide power of the SSD 4200. Exemplarily, the auxiliary power supply 4230 may be located in the SSD 4200, or be located at the outside of the SSD 4200. For example, the auxiliary power supply 4230 may be located on a main board and may provide auxiliary power to the SSD 4200.

The buffer memory 4240 may be used as a buffer memory of the SSD 4200. For example, the buffer memory 4240 may temporarily store data received from the host 4100 or data received from the plurality of memory devices 4221 to 422n or may temporarily store meta data (e.g., a mapping table) of the plurality of memory devices 4221 to 422n. The buffer memory 4240 may include volatile memories, such as a DRAM, an SDRAM, a DDR SDRAM, an LPDDR SDRAM, and a GRAM or nonvolatile memories such as a FRAM, a ReRAM, an STT-MRAM, and a PRAM.

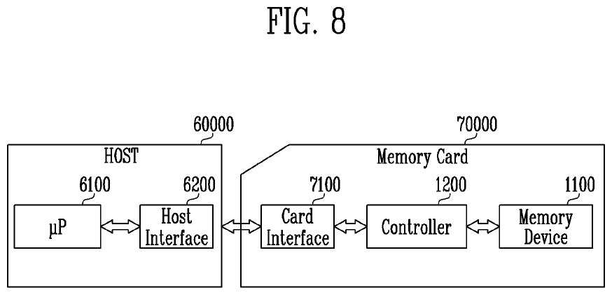

FIG. 8 is a diagram illustrating a memory card system to which the memory device of the present disclosure is applied.

Referring to FIG. 8, the memory system 70000 may be implemented as a memory card or a smart card. The memory system 70000 may include a memory device 1100, a controller 1200, and a card interface 7100.

The memory device 1100 may be configured identically to the memory device 100, shown in FIG. 1.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto.

The card interface 7100 may interface data exchange between a host 60000 and the controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the controller 1200 under the control of a microprocessor (pP) 6100.

In accordance with the present disclosure, the structural stability of the memory device can be improved.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a stack structure including a plurality of conductive layers and a plurality of insulating layers, which are alternately stacked in a first direction;
a plurality of first plugs disposed in the stack structure, the plurality of first plugs extending in the first direction; and
a first support structure disposed in the stack structure, the first support structure being adjacent to at least one of the plurality of first plugs,
wherein the first support structure includes an insulating structure and a second plug, which are stacked in the first direction, and
wherein each of the plurality of first plugs and the second plug includes a channel layer.

2. The memory device of claim 1, further comprising a plurality of contact plugs connected to the plurality of conductive layers,
wherein the stack structure includes a contact region having the plurality of contact plugs and a cell region having the plurality of first plugs, and
wherein the first support structure is disposed between the contact region of the stack structure and the cell region of the stack structure.

3. The memory device of claim 1, further comprising a slit isolating the stack structure into a first memory cell array and a second memory cell array,
wherein at least one of the plurality of first plugs is adjacent to the first support structure in a direction in which the slit extends.

4. The memory device of claim 1, comprising a plurality of second support structures disposed in the stack structure at both ends of the stack structure with the plurality of first plugs interposed therebetween,
wherein the first support structure is disposed between the plurality of second support structures and the plurality of first plugs.

5. The memory device of claim 4, wherein the plurality of second support structures include an insulating material extending longer in the first direction than the insulating structure of the first support structure.

6. The memory device of claim 1, wherein a length of the second plug is shorter than a length of the plurality of first plugs in the first direction.

7. The memory device of claim 1, wherein a length of the insulating structure is shorter than a length of the plurality of first plugs in the first direction.

8. The memory device of claim 1, wherein the bottom of the insulating structure and the bottom of the plurality of first plugs are substantially on the same plane.

9. The memory device of claim 1, further comprising a source layer disposed on the bottom of the stack structure,
wherein the channel layers of the plurality of first plugs are connected to the source layer, and
wherein the channel layer of the second plug is spaced apart from the source layer by the insulating structure.

10. The memory device of claim 9, wherein the insulating structure is connected to the source layer.

11. The memory device of claim 1, wherein each of the plurality of first plugs and the second plug further includes a tunnel insulating layer, a data storage layer, and a blocking layer, which surround the channel layer.

12. The memory device of claim 1, wherein each of the plurality of first plugs has a stepped corner portion on a sidewall thereof.

13. The memory device of claim 12, wherein the corner portion of each of the plurality of first plugs and an upper surface of the insulating structure are substantially on the same plane.

14. A memory device comprising:
a first stack structure including a plurality of first insulating layers and a plurality of first conductive patterns, which are alternately stacked in a first direction;
a second stack structure including a plurality of second insulating layers and a plurality of second conductive patterns, which are alternately stacked in the first direction, wherein the second stack structure is formed on the first stack structure;
a first plug extending through the first stack structure and the second stack structure;
an insulating structure disposed in the first stack structure; and
a second plug disposed in the second stack structure, the second plug being connected to the insulating structure in the first direction,
wherein each of the first plug and the second plug includes a channel layer.

15. A method of manufacturing a memory device, the method comprising:
forming a first stack structure including a plurality of first and second material layers alternately disposed in a first direction;
forming a first gap fill layer and an insulating structure in the first stack structure;
forming a second stack structure including third and fourth material layers alternately disposed in the first direction on the first stack structure;
forming, in the second stack structure, a first upper hole exposing the first gap fill layer and a second upper hole exposing the insulating structure;
forming a first lower hole in the first stack structure by removing the first gap fill layer;
forming a first plug in the first lower hole and the first upper hole, extending through the first and second stack structures; and
forming a second plug in the second upper hole, the second plug extending through the second stack structure and being connected to the insulating structure.

16. The method of claim 15, wherein the forming of the insulating structure and the first gap fill layer includes:
forming the first lower hole and a second lower hole in the first stack structure;
forming a first gap fill layer in the first lower hole and a second gap fill layer in the second lower hole; and
replacing the second gap fill layer with the insulating structure.

17. The method of claim 16, wherein the first stack structure is formed on a source layer,
wherein the first lower hole and the second lower hole are formed to expose the source layer, and
wherein the insulating structure is in contact with the source layer.

18. The method of claim 16, wherein the first and second gap fill insulating layers include at least one of tungsten (W), carbon (C), and molybdenum.

19. The method of claim 16, wherein the replacing of the second gap fill layer with the insulating structure includes:
forming, on the first stack structure, a hard mask which blocks the first gap fill layer and exposes the second gap fill layer;
removing the second gap fill layer to form the second lower hole;
filling the second lower hole with the insulating structure; and
removing the hard mask.

20. The method of claim 15, wherein the forming of the first plug and the second plug includes:
sequentially forming a blocking layer, a data storage layer, and a tunnel insulating layer on a surface of each of the first lower hole, the first upper hole, and the second upper hole;
forming a vertical hole penetrating the tunnel insulating layer, the data storage layer, and the blocking layer in each of the first lower hole and the second upper hole, the vertical hole extending to a bottom surface of the first lower hole and the bottom surface of the second upper hole; and
forming a channel layer in the vertical hole, the channel layer filling a space within the tunnel insulating layer.

21. The method of claim 20, wherein the first stack structure is formed on a source layer;
wherein the channel layer of the first plug is connected to the source layer, and
wherein the channel layer of the second plug is connected to the insulating structure.
